(19) United States
(12) Patent Application Publication
(10) Pub. No.: US 2026/0323899 A1
(43) Pub. Date: Oct. 15, 2026

(54) SUPERVISION APPARATUS, MOBILE WORK DEVICE, SURFACE-MOUNTING SYSTEM, SUPERVISION METHOD, AND METHOD OF CONTROLLING MOBILE WORK DEVICE

(71) Applicant: FUJI CORPORATION, Chiryu (JP)

(72) Inventor: Yukitoshi MORITA, Okazaki-shi (JP)

(73) Assignee: FUJI CORPORATION, Chiryu (JP)

(21) Appl. No.: 19/485,903

(22) PCT Filed: Jul. 7, 2023
(86) PCT No.: PCT/JP2023/025290

§ 371 Date: Nov. 19, 2025

(51) Int. Cl. H05K 13/08; H05K 13/02; H05K 13/04

(52) U.S. Cl. CPC H05K 13/08; H05K 13/02; H05K 13/04

(57) ABSTRACT

A supervision apparatus according to the present disclosure includes a supervision control section configured to, after a feeder in a common setup for installing the feeders that hold a common component at a common position in production of multiple types of processing target objects is installed in a mounting installation section, at a predetermined timing when the production of the processing target object by the common setup ends, output a restoration command for moving the feeder included in the common setup and not located in the mounting installation section to an installation position of the common setup to a mobile work device.

### TECHNICAL FIELD

The present description discloses a supervision apparatus, a mobile work device, a mounting system, a supervision method, and a method of controlling a mobile work device.

### BACKGROUND ART

In the conventional art, as a mounting system, a mounting system has been proposed in which a mounting process is started in a state in which some feeders that are initial setting targets among multiple feeders necessary for the mounting process are set in a supply area of a component mounter and the remaining feeders are not set in the supply area, and the mounting process is performed while exchanging the feeders in which the supply of the components ends with the remaining feeders using a mobile work device (for example, see Patent Literature 1). In this mounting system, since the mounting process can be performed while exchanging the feeder with a necessary feeder within a range of an upper limit of the number of mounting devices to be installed, the efficiency of the mounting process can be improved.

### CITATION LIST

### Patent Literature Patent Literature 1: WO 2017/085782

### BRIEF SUMMARY

### Technical Problem

Meanwhile, in the mounting system, there is a case where the mounting process is executed while collectively exchanging a group of the feeders that are the initial setting targets as a common setup. In this mounting system, it is possible to minimize an on-line set up time and to further improve the efficiency. However, in the mounting system of Patent Literature 1, since the feeder that is not currently used is moved to a standby installation section as a stock area, in some cases, the common setup is not maintained, and the feeders cannot be collectively exchanged. In such a mounting system, it has been required to further improve the efficiency.

An object of the present disclosure is to provide a supervision apparatus, a mobile work device, a mounting system, a supervision method, and a method of controlling a mobile work device that can further improve the efficiency in mounting systems for automatically exchanging feeders.

The present disclosure adopts the following means to achieve the above-described object.

A supervision apparatus of the present disclosure is
a supervision apparatus for use in a mounting system including a mounting device including a mounting section configured to execute a mounting process of a component on a processing target object, a supply section including a mounting installation section in which a feeder that holds the component is installed, the supply section being configured to supply the component, and a mounting control section configured to cause the mounting section to pick up the component from the supply section, and a mobile work device configured to automatically exchange the feeders between a standby installation section in which the mounting process is not executable and the mounting installation section, the supervision apparatus including:
a supervision control section configured to, after the feeders in a common setup for installing the feeders that hold a common component at a common position in production of multiple types of the processing target objects are installed in the mounting installation section, at a predetermined timing when the production of the processing target object by the common setup ends, output a restoration command for moving the feeder included in the common setup and not located in the mounting installation section to an installation position of the common setup to the mobile work device.

In this supervision apparatus, at the predetermined timing when the production of the processing target object by the common setup ends, when the feeder in the common setup is not located in the mounting installation section, the restoration command for moving the feeder to the installation position of the common setup is output to the mobile work device. In this supervision apparatus, since the feeder disposition of the common setup is restored when the production in the common setup ends, the feeders can be collectively exchanged, and thus the efficiency can be further improved by shortening an on-line set up time.

### BRIEF DESCRIPTION OF DRAWINGS

FIG. 1 is a schematic diagram illustrating an example of mounting system 10.

FIG. 2 is a diagram schematically illustrating configurations of mounting device 15 and loader 18.

FIG. 3 is a diagram illustrating an example of production plan information 44 stored in storage section 43.

FIG. 4 is a flowchart illustrating an example of an execution condition setting processing routine.

FIG. 5 is a diagram illustrating an example of execution condition input screen 80.

FIG. 6 is a flowchart illustrating an example of a mounting supervision processing routine.

FIG. 7 is a diagram illustrating an example of a process of executing a mounting job in a common setup.

FIG. 8 is a diagram illustrating an example of the process of executing the mounting job in the common setup.

### DESCRIPTION OF EMBODIMENTS

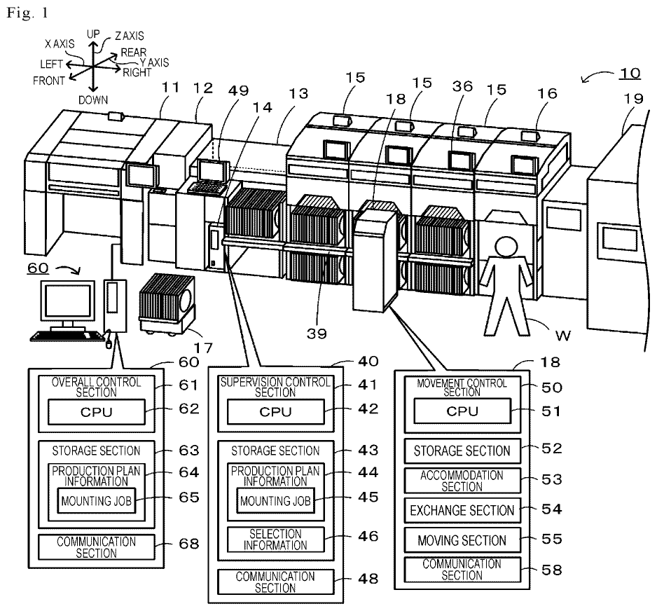

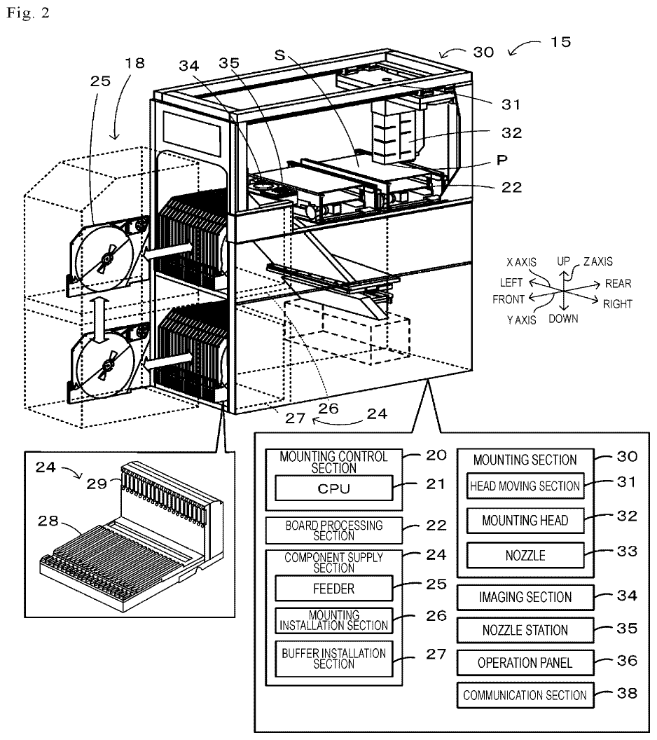

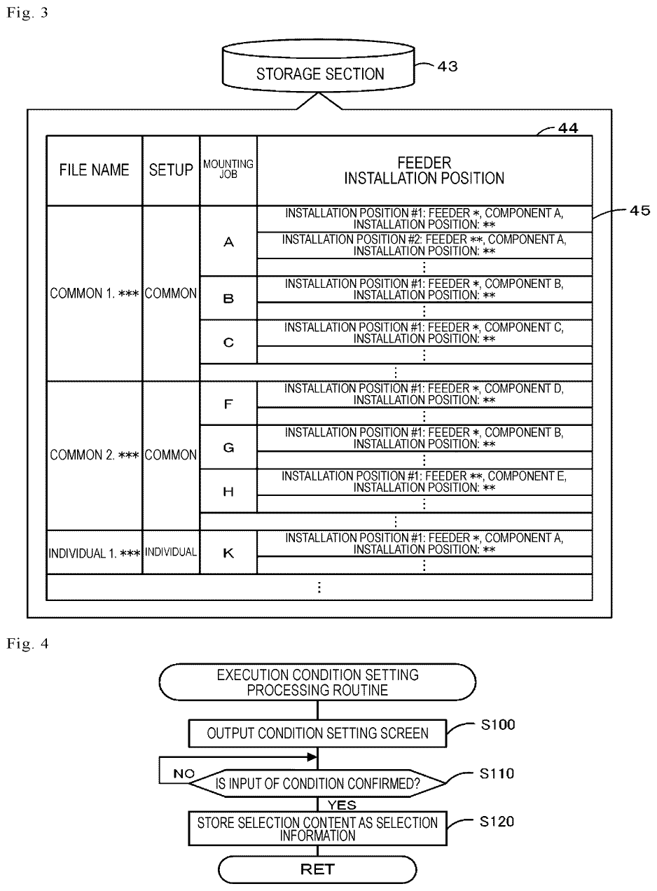

The present embodiment will be described below with reference to the accompanying drawings. FIG. 1 is a schematic diagram illustrating an example of mounting system 10 of the present disclosure. FIG. 2 is a diagram illustrating schematic configurations of mounting device 15 and loader 18 that is a mobile work device. FIG. 3 is a diagram illustrating an example of production plan information 44 stored in storage section 43 of supervision apparatus 14. In the present embodiment, a left-right direction (X axis), a front-rear direction (Y axis), and an up-down direction (Z axis) are as illustrated in FIGS. 1 and 2.

Mounting system 10 is configured, for example, as a production line in which devices that execute a mounting process of components P on board S as a processing target object illustrated in FIG. 2 are arranged in a conveyance direction of board S. Here, the processing target object will be described as board S, but the processing target object is not limited in particular as long as the processing target object is an object on which component P is mounted, and may be a substrate having a three-dimensional shape. As illustrated in FIG. 1, mounting system 10 includes printing device 11, printing inspection device 12, storage device 13, supervision apparatus 14, mounting device 15, mounting inspection device 16, automated guided vehicle 17, loader 18, reflow device 19, supervisory device 60, and the like.

Printing device 11 is a device that prints viscous fluid such as a solder paste, a conductive paste, or an adhesive, on board S. Printing inspection device 12 is a device that inspects a state of the printed viscous fluid. Storage device 13 is a storage place for storing feeders 25 as supply members for use in mounting device 15. Storage device 13 is provided in a front lower portion of a conveyance device between printing inspection device 12 and mounting device 15. Supervision apparatus 14 is a device that supervises feeders 25 stored in storage device 13. Mounting inspection device 16 is a device that inspects a state or the like of component P mounted on board S. Reflow device 19 is a device that reflows board S on which the viscous fluid is printed and component P is mounted.

As illustrated in FIG. 1, storage device 13 is a device that temporarily stores feeders 25 as supply devices for use in mounting device 15. Storage device 13 includes the conveyance device that conveys board S and supervision apparatus 14 that supervises information, and is provided between printing inspection device 12 and mounting device 15. Storage device 13 includes a storage installation section having slot 28 and connection section 29 similar to mounting installation section 26 and buffer installation section 27 provided in component supply section 24 described later. When feeder 25 is connected to the installation section, a controller of feeder 25 outputs information on feeder 25 to supervision apparatus 14 connected to storage device 13. In storage device 13, feeders 25 are conveyed by automated guided vehicle 17, or feeders 25 may be conveyed by worker W.

Supervision apparatus 14 is disposed in storage device 13 and is configured as a server that supervises information on mounting device 15 of mounting system 10. Supervision apparatus 14 includes supervision control section 41 that controls the entire device, storage section 43 that stores various information, communication section 48 that performs bidirectional communication with an external device such as automated guided vehicle 17 or loader 18, and display section 49 that displays a screen in an upper portion. Supervision apparatus 14 creates and supervises production plan information 44 used for the mounting process of component P or mounting job 45 included in production plan information 44, and acquires and supervises information on mounting system 10.

As illustrated in FIG. 3, storage section 43 stores production plan information 44 including one or more mounting jobs 45 used when producing each board S as the processing target object and selection information 46. Supervision apparatus 14 acquires production plan information 64 created by supervisory device 60 via a communication line, and stores the information in storage section 43 as production plan information 44. Mounting job 45 is set for each board S as a product to be produced. Mounting job 45 includes information on the installation position of feeders 25 that hold component P or the type and the number of components P disposed on specific board S, or information on the disposition order and the disposition position of components P mounted on board S. Mounting device 15 includes an individual setup and a common setup as the installation positions of respective feeders 25. The individual setup is a setup for installing feeders 25 as the supply members at individual positions in each production of multiple types of boards S. The common setup is a setup for installing feeders 25 as the supply members that hold common component P at a common position in the production of multiple types of boards S. In the individual setup, since feeders 25 can be installed at a unique position in the production of each board S, it is possible to further shorten the production time, but it is necessary to remove and install feeders 25 many times during the changeover for switching mounting job 45. In the common setup, since feeder 25 that holds same component P is installed at the same position over the production of multiple boards S, flexibility such as slot consumption and shortening of the production time may be insufficient, but movement of feeder 25 is not necessary during the changeover in which mounting job 45 is switched. Selection information 46 includes a retraction method of feeder 25 of the common setup and a restoration time of feeder 25 of the common setup. The retraction method defines how feeder 25 unnecessary for the production of board S is retracted from mounting installation section 26 to the standby installation section when the production of the common setup is executed. The restoration time refers to a timing at which retracted feeder 25 is returned to mounting installation section 26 and the installation state of feeders 25 in the common setup is restored.

Mounting device 15 is a device that picks up the components and mounts the components on board S. Mounting device 15 includes mounting control section 20, board processing section 22, component supply section 24, mounting section 30, imaging section 34, nozzle station 35, operation panel 36, and communication section 38. Mounting control section 20 is configured as a microprocessor centered on CPU 21 and controls the entire device, as illustrated in FIG. 2. Mounting control section 20 outputs control signals to board processing section 22, component supply section 24, mounting section 30, imaging section 34, and operation panel 36, and inputs signals from board processing section 22, component supply section 24, mounting section 30, imaging section 34, and operation panel 36. Mounting control section 20 includes a storage section which stores the mounting job including information on component P and information on a disposition order and the disposition position in which components P are mounted on board S, the installation positions of feeders 25 that pick up component P, or the like. The mounting job stored in the storage section includes information similar to mounting job 45 illustrated in FIG. 3.

Board processing section 22 executes processes of loading, conveying, fixing at an installation position, and unloading board S, as well as a process of supporting board S from below using a support member. Board processing section 22 includes a pair of conveyor belts that are provided at an interval in the front-rear direction while being stretched in the left-right direction in FIG. 1. Board S is conveyed by the conveyor belts.

Component supply section 24 is a unit that supplies component P to mounting section 30. In component supply section 24, feeders 25 as the supply members including a reel wound with a tape as a holding member that holds the component is installed in one or more installation sections. As illustrated in FIG. 2, component supply section 24 has two upper and lower installation sections in which feeders 25 can be installed, on a front side of the device. The upper stage is mounting installation section 26 from which the component can be picked up by mounting section 30, and the lower stage is buffer installation section 27 from which the component cannot be picked up by mounting section 30. Here, mounting installation section 26 and buffer installation section 27 are collectively referred to as an installation section. Here, buffer installation section 27 and the storage installation section of storage device 13 are collectively referred to as a standby installation section. In component supply section 24, multiple slots 28 that are arranged in the X direction at predetermined intervals and into which rail members of feeders 25 are inserted, and connection sections 29 into which connectors provided at distal ends of feeders 25 are inserted are disposed. Feeder 25 includes the controller (not illustrated). The controller stores information, such as ID of the tape in feeder 25, a component type, or the number of remaining components. When feeder 25 is connected to connection section 29, the controller transmits the information on feeder 25 to mounting control section 20.

Mounting section 30 is a unit that picks up component P from component supply section 24 and places component P on board S fixed to board processing section 22. Mounting section 30 includes head moving section 31, mounting head 32, and nozzle 33. Head moving section 31 includes a slider that moves by being guided by guide rails in the XY directions, and a motor that drives the slider. Mounting head 32 picks up one or more components and is moved in the XY directions by head moving section 31. Mounting head 32 is detachably installed in the slider. One or more nozzles 33 are detachably installed in a lower surface of mounting head 32. Nozzle 33 picks up the component using a negative pressure. There are multiple types of nozzles 33 adapted for each type or size of component P. There are multiple types of mounting heads 32, and the types and the number of nozzles 33 that can be installed are set for each type. Mounting head 32 is set so that, for example, one or two nozzles 33 can be installed for a large component, and any of 4, 6, 8, 12, and 16 nozzles 33 can be installed for a general-purpose component. A pickup member that picks up the component may be a mechanical chuck or the like that mechanically holds the component instead of nozzle 33.

Imaging section 34 is a camera that captures upward images, and captures an image of component P or the like held by mounting head 32. Imaging section 34, as illustrated in FIG. 1, is a device that captures images of one or more components P picked up and held by mounting head 32. Imaging section 34 is disposed between component supply section 24 and board processing section 22. Imaging section 34 captures one or two or more images when mounting head 32 that holds component P passes above imaging section 34, and outputs the captured images to mounting control section 20. Mounting control section 20 can check the pickup position, the shape, or the like of component P from the captured images of imaging section 34. Nozzle station 35 is an accommodation section in which various nozzles 33 for use in mounting section 30 are on standby. Operation panel 36 is a unit that receives the input from worker W and presents information to worker W. Operation panel 36 is disposed on a front surface of mounting device 15, and includes a display section serving as a display and an operation section having a touch panel and buttons. Communication section 38 is an interface for exchanging information with external devices such as supervision apparatus 14 and supervisory device 60.

Automated guided vehicle 17 conveys members for use in mounting system 10, for example, printing-related members for use in printing device 11, or conveys mounting-related members for use in loader 18. Automated guided vehicle 17 automatically conveys, for example, the printing-related members or the mounting-related members between a warehouse (not illustrated) and storage device 13. The mounting-related members include, for example, feeders 25 as the supply devices, the support member of board S, mounting head 32 and nozzle 33 as the pickup members. Here, it is assumed that automated guided vehicle 17 mainly conveys feeders 25. Automated guided vehicle 17 may be configured as an automatic guided vehicle (AGV) that moves on a predetermined track, or may be configured as an autonomous mobile robot (AMR) that moves to a destination on a free route by detecting surroundings thereof.

Loader 18 is a mobile work device and is a device that moves within a movement region in front of mounting system 10 and automatically collects and replenishes feeders 25 of mounting device 15. Loader 18 includes movement control section 50, storage section 52, accommodation section 53, exchange section 54, moving section 55, and communication section 58. Movement control section 50 is configured as a microprocessor centered on CPU 51 and controls the entire device. Storage section 52 is, for example, HDD or the like that stores various data, such as processing programs, and stores information on the exchange operation. Accommodation section 53 has an accommodation space in which feeders 25 are accommodated. Accommodation section 53 is configured to accommodate, for example, four feeders 25. Exchange section 54 is a mechanism that moves feeder 25 in and out as well as moving feeder 25 in the up-down direction (see FIG. 2). Exchange section 54 has a clamp section that clamps feeder 25, a Y-axis slider that moves the clamp section in the Y-axis direction (front-rear direction), and a Z-axis slider that moves the clamp section in the Z-axis direction (up-down direction). Exchange section 54 executes installation and removal of feeder 25 at mounting installation section 26, and installation and removal of feeder 25 at buffer installation section 27. Moving section 55 is a mechanism that moves loader 18 in the X-axis direction (left-right direction) along X-axis rail 39 disposed on the front surface of mounting device 15. Communication section 58 is an interface for exchanging information with external devices such as supervision apparatus 14 and mounting device 15. Loader 18 outputs the current position or executed work content to supervision apparatus 14. Loader 18 can automatically attach and detach feeders 25 as the supply members, and may also be configured to collect and replenish the mounting-related members, the printing-related members, or the like.

Supervisory device 60 (see FIG. 1) is configured as a server that supervises information on each device of mounting system 10. Supervisory device 60 includes overall control section 61 that controls the entire device, storage section 63 that stores various information, and communication section 68 that executes bidirectional communication with an external device, such as mounting system 10, automated guided vehicle 17, and loader 18. Supervisory device 60 creates and supervises production plan information 64 used for the mounting process of the component or mounting job 65 included in production plan information 64, and acquires and supervises information on mounting system 10.

Next, of an operation of mounting system 10 of the present embodiment configured as described above, first, processing in which supervisory device 60 creates production plan information 64 will be described. When this processing is started, first, CPU 62 of overall control section 61 acquires information on boards S which are all the processing target objects manufactured in the current production plan. For example, CPU 62 acquires the type of component P, the number of components, and the like from the data of board S which is the product, and acquires the number of modules or the number of installation sections of mounting device 15 from the configuration of mounting system 10. Next, CPU 62 sets mounting job 65 for each board S to be produced. CPU 62 sets the common setup including multiple mounting jobs 65 and the individual setup based on information selected in advance by worker W. For example, as illustrated in FIG. 3, CPU 62 creates production plan information 64 including the common setup including mounting jobs A to E, the common setup including mounting jobs F to J, and the individual setup including mounting job K. Supervisory device 60 outputs production plan information 64 created in this way to supervision apparatus 14 where the production line that executes the production process is provided.

Next, processing in which mounting device 15 mounts component P on board S based on production plan information 44 will be described. Here, the mounting process of the individual setup will be mainly described. When the mounting process is started, CPU 21 of mounting control section 20 acquires mounting job 45 of the product to be manufactured this time from supervision apparatus 14. CPU 21 may acquire mounting job 45 of the own device from supervision apparatus 14 for each product or may acquire mounting job 45 from supervisory device 60. Loader 18 executes a changeover process of installing each feeder 25 at the installation position set in mounting job 45. When the production can be started, CPU 21 causes board processing section 22 to load and fix board S. Next, based on mounting job 45, CPU 21 executes processing of causing mounting head 32 to pick up component P from feeder 25 installed in component supply section 24 and place component P on board S. When the disposition of component P on board S ends, CPU 21 discharges board S to board processing section 22, and repeatedly executes the processing described above. CPU 21 supervises the number of components consumed by each feeder 25 during the mounting process, and when the number of remaining components is equal to or less than a predetermined warning value, CPU 21 transmits the exchange information indicating that the number of remaining components is equal to or less than the predetermined warning value to supervision apparatus 14. Supervision apparatus 14 causes loader 18 to execute the exchange operation of feeder 25 based on the exchange information. Loader 18 moves between storage device 13 and mounting device 15 along X-axis rail 39, and executes a process of exchanging feeders 25 in mounting device 15 as an operation target. When the manufacturing of current board S ends, it is determined whether there is next production of board S, and when there is next production, loader 18 is caused to execute the changeover process. Loader 18 executes a process of installing each feeder 25 at the installation position of next mounting job 65.

Next, the setting of the execution conditions in the changeover process in the common setup performed by mounting device 15 will be described. FIG. 4 is a flowchart illustrating an example of an execution condition setting processing routine executed by supervision control section 41 of supervision apparatus 14. This routine is stored in storage section 43 of supervision apparatus 14, and is executed based on the input of worker W before the production process of board S is started. When this routine is started, first, CPU 42 of supervision control section 41 outputs an execution condition setting screen in order to acquire the execution conditions in the changeover process in the common setup (S100). Supervision apparatus 14 displays and outputs execution condition input screen 80 to display section 49.

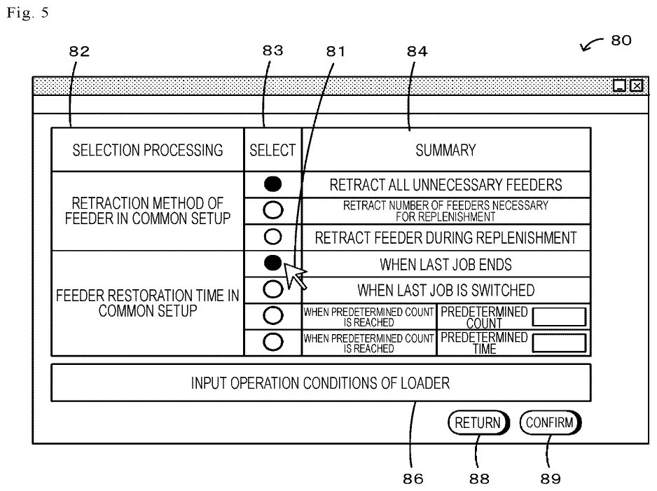

FIG. 5 is a diagram illustrating an example of execution condition input screen 80 displayed and output on display section 49. Execution condition input screen 80 includes cursor 81, selection processing display field 82, selection input field 83, summary display field 84, message display field 86, return key 88, and confirm key 89. Cursor 81 is configured to be movable by an operation of worker W in order for worker W to select an input position. Selection processing display field 82 is a field for displaying selection processing of the execution conditions of the common setup. Selection input field 83 is a field for inputting the selection. Summary display field 84 is a field indicating a summary of options. Message display field 86 is a field for displaying a message to worker W. Return key 88 is a key for returning the display screen of display section 49 to the previous screen. Confirm key 89 is a key for confirming the selection of the selection processing. The selection processing of the execution conditions includes the retraction method of feeder 25 of the common setup and the restoration time of feeder 25. The options of the retraction method include a case where all unnecessary feeders 25 among feeders 25 of the common setup are retracted to buffer installation section 27, a case where the number of feeders 25 necessary for replenishment when the component runs out is retracted to buffer installation section 27, and a case where feeder 25 is retracted to buffer installation section 27 when the component of feeder 25 runs out. The options of the restoration time include, for example, when the last mounting job in the common setup ends, when the common setup ends and the mounting job is switched to the next mounting job, and when a predetermined count is reached immediately before the end of the common setup. The phrase “when the predetermined count is reached” includes, for example, options, that is, the predetermined count before the last mounting job in the common setup ends and a predetermined time before the last mounting job in the common setup ends. Worker W can select the option of the retraction method and the option of the restoration time, and confirm the input content by pressing confirm key 89.

After S100, CPU 42 determines whether the input of the execution conditions is confirmed (S110), and when the input is not confirmed, CPU 42 remains on standby. On the other hand, when the input of the execution conditions is confirmed, CPU 42 stores the selection content of which the input is confirmed on execution condition input screen 80 in storage section 43 as selection information 46 including the selection content as the execution conditions (S120), and ends the routine. As described above, in supervision apparatus 14, the execution conditions in the common setup are set in advance, for example, before the start of the mounting process.

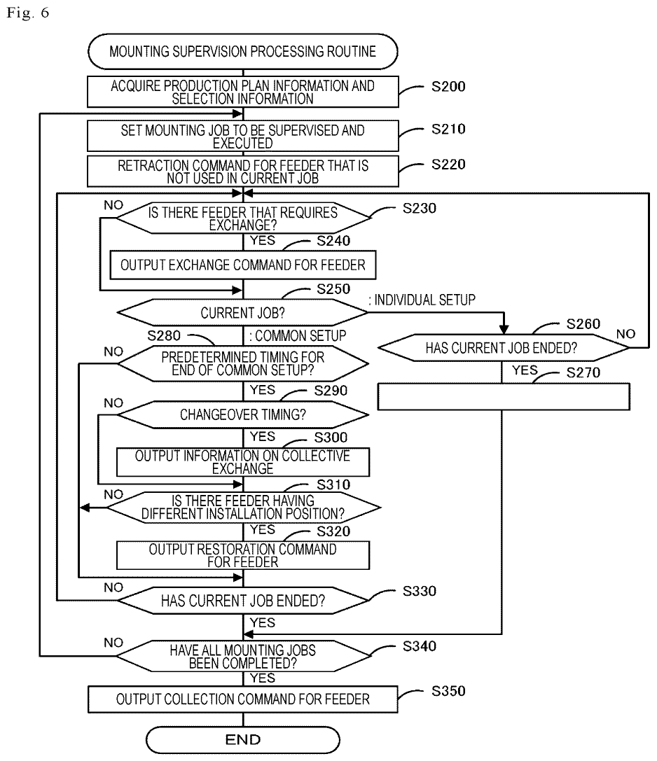

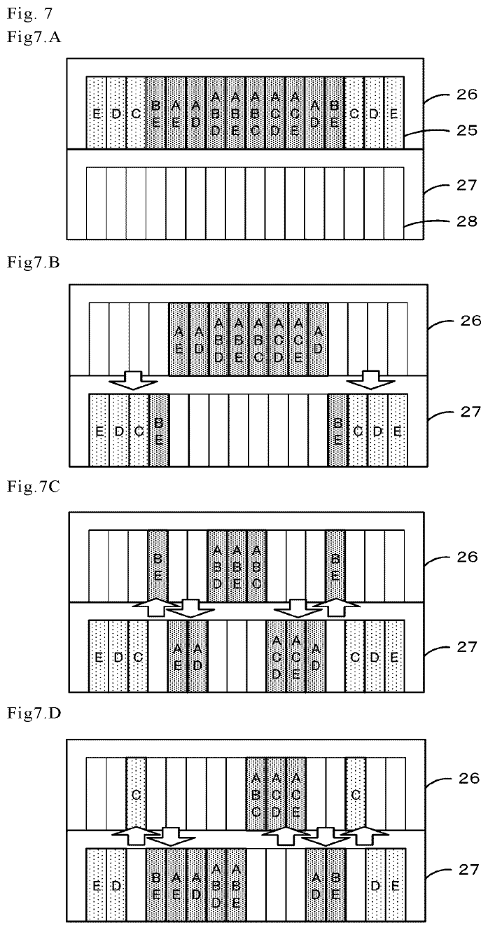

Next, processing in which supervision apparatus 14 issues a command to loader 18 during the mounting process by mounting device 15 will be described. FIG. 6 is a flowchart illustrating an example of a mounting supervision processing routine executed by supervision control section 41 of supervision apparatus 14. This routine is stored in storage section 43 of supervision apparatus 14, and is executed based on the input of worker W when the production process of board S is started. In addition, in accordance with the start of this routine, for example, in a case where the production is started from mounting job 45 of the common setup, worker W installs the feeder group to component supply section 24 of corresponding mounting device 15 by collective installation using a feeder magazine changer in which feeders 25 are arranged at the installation positions defined in the common setup (see FIG. 7A described later). The feeder magazine changer is a cart including slot 28 similar to mounting installation section 26. The feeder magazine changer is configured such that when the feeder magazine changer is brought close to component supply section 24 while facing component supply section 24, the feeder group in the slot can be collectively installed on mounting installation section 26 of component supply section 24. In addition, the feeder magazine changer is configured such that when the feeder group is brought close to mounting installation section 26 in which the feeder group is installed with slots empty, the feeder group can be collectively removed. As described above, in mounting system 10, when the feeder magazine changer is used, the changeover time can be shortened. After installing feeder 25, worker W starts the mounting process of mounting device 15 and starts this routine.

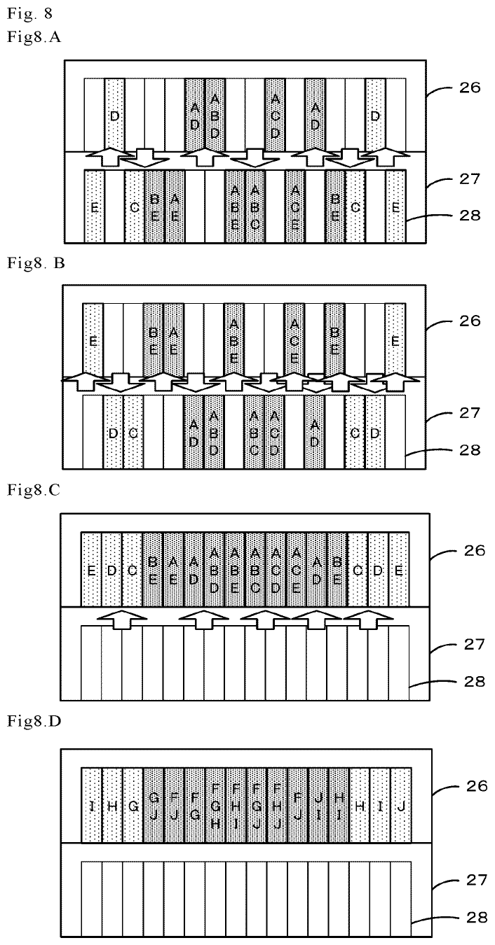

When this routine is started, first, CPU 42 of supervision control section 41 reads and acquires production plan information 44 and selection information 46 from storage section 43 (S200), and sets mounting job 45 in which the mounting process is executed in mounting device 15 as mounting job 45 to be supervised and executed (S210). For example, in the example of FIG. 3, CPU 42 first sets mounting job A as the execution job based on the order set in production plan information 44 in the common setup. Here, examples illustrated in FIGS. 3, 7, and 8 will be described as specific examples. FIGS. 7 and 8 are diagrams illustrating an example of the process of executing the mounting job in the common setup. In FIGS. 7 and 8, the number of the mounting job used among mounting jobs A to E and F to J is illustrated in feeder 25. In FIG. 7, FIG. 7A is a diagram illustrating an installation state of common setup 1, FIG. 7B is a diagram in which feeder 25 that is not used is retracted to buffer installation section 27 when mounting job A is executed, FIG. 7C is a diagram in which feeders 25 that are used and not used are exchanged when mounting job B is executed, and FIG. 7D is a diagram in which feeders 25 that are used and not used are exchanged when mounting job C is executed. In addition, in FIG. 8, FIG. 8A is a diagram in which feeders 25 that are used and not used are exchanged when mounting job D is executed, FIG. 8B is a diagram in which feeders 25 that are used and not used are exchanged when mounting job E is executed, FIG. 8C is a diagram in which the installation state of common setup 1 is restored, and FIG. 8D is a diagram illustrating the installation state of common setup 2.

After S210, CPU 42 outputs, to loader 18, a command for retracting feeder 25 that is not used in the currently executed mounting job on the standby installation section (S220). CPU 42 sets the retraction command based on the execution conditions set in selection information 46. In mounting device 15, when there is an empty slot in mounting installation section 26, it is possible to efficiently execute the feeder exchange by using the empty slot for the feeder exchange when the component runs out. In mounting device 15, the component run-out timing can also be grasped during setting of production plan information 44 from the cycle time of the mounting process obtained by experience, and the minimum number of empty slots necessary for the feeder exchange can also be calculated. Therefore, in selection information 46, as illustrated in FIG. 5, retracting the number of feeders necessary for replenishment is also defined as an option. Loader 18 that has received the retraction command moves feeder 25 that is not used to buffer installation section 27 as the standby installation section based on the retraction command (FIGS. 7A and 7B). When there is no empty slot in buffer installation section 27 of corresponding mounting device 15, loader 18 may retract unused feeder 25 to buffer installation section 27 of neighboring mounting device 15. When there is no empty slot in neighboring buffer installation section 27, loader 18 may retract unused feeder 25 to the storage installation section of storage device 13.

Next, CPU 42 determines whether there is feeder 25 that requires exchange (S230). CPU 42 determines whether there is feeder 25 that requires exchange based on the number of used components, the number of remaining components, and the like. When there is a feeder that requires exchange, CPU 42 outputs an exchange command for corresponding feeder 25 to loader 18 (S240). Loader 18 that has received the exchange command executes the exchange process between feeder 25 of the exchange source and new feeder 25 based on the exchange command. New feeder 25 may be provided in an empty slot of mounting installation section 26, buffer installation section 27, the storage installation section of storage device 13, or the like.

After S240 or when there is no feeder 25 that requires exchange in S230, CPU 42 determines whether the currently executed mounting job is the individual setup or the common setup (S250). When the currently executed mounting job is the individual setup, CPU 42 determines whether to continue or end the current mounting job (S260). When the current mounting job is continued, that is, when the production of board S being executed has not ended, CPU 42 executes the processing in and after S230. On the other hand, when the current mounting job ends, that is, when the production of board S in this mounting job ends, CPU 42 switches to the next mounting job and outputs the changeover command for executing changeover to loader 18 (S270). In the individual setup, loader 18 that has received the changeover command executes the exchange operation of feeder 25 installed in mounting installation section 26 based on the changeover command.

On the other hand, when the currently executed mounting job is the common setup in S250, CPU 42 determines whether the current time has reached the predetermined timing for the end of the common setup (S280). CPU 42 can use the “feeder restoration time of the common setup” set in selection information 46 to determine whether the predetermined timing has arrived. CPU 42 may use, as the predetermined timing, any one or more of a timing when the last mounting job in the common setup ends, a timing after the common setup ends and before the mounting job of the next production is executed, a timing a predetermined count before the last mounting job in the common setup ends, and a timing a predetermined time before the last mounting job in the common setup ends. The “predetermined count before” and the “predetermined time before” can be set to values obtained by empirically obtaining the number of boards and the time for which the installation state of feeder 25 defined in the common setup can be restored and adding a margin thereto as necessary. In addition, CPU 42 may monitor the file name being executed for the mounting job, and determine the end timing of the last mounting job in the common setup by changing the file name. The file name may be, for example, a file name of the mounting job or a file name of the common setup.

In S280, when the current time has not reached the predetermined timing for the end of the common setup, CPU 42 determines whether the current mounting job has ended, that is, whether the production of board S being executed has ended (S330). When the current mounting job has not ended, CPU 42 executes the processing in and after S230. That is, CPU 42 determines whether the currently executed mounting job ends while determining whether the predetermined timing has arrived. On the other hand, when the current mounting job has ended in S330, that is, when the production of board S being executed has ended, or after S270, CPU 42 determines whether all the mounting jobs have been completed, that is, whether the production under production plan information 44 has been completed (S340). When all the mounting jobs have not been completed, CPU 42 executes the processing in and after S210. That is, CPU 42 continuously executes the production of board S in accordance with production plan information 44.

On the other hand, when the current time has reached the predetermined timing for the end of the common setup, CPU 42 determines whether the current time has reached the changeover timing (S290). When the current time is the changeover timing, CPU 42 outputs information indicating that feeders 25 are collectively exchanged to worker W (S300). CPU 42 may cause display section 49 to display a message to that effect. Worker W who has checked this information executes the collective exchange operation of feeder 25 using, for example, the feeder magazine changer. After S300 or when the changeover timing has not arrived in S290, CPU 42 determines whether there is feeder 25 having a different installation position in the installation state of the common setup of mounting installation section 26 (S310). For example, when there is feeder 25 retracted to the standby installation section, CPU 42 determines that there is feeder 25 having a different installation position. When there is feeder 25 having a different installation position, CPU 42 outputs the restoration command for the installation position of corresponding feeder 25 to loader 18 (S320). Loader 18 that has received the restoration command executes an operation of moving feeder 25 having a different installation position to the installation position of the common setup.

After S320, or when the current time has not reached the predetermined timing for the end of the common setup in S280, or when there is no feeder 25 having a different installation position in S310, CPU 42 executes the processing in and after S330. Then, when all the mounting jobs have been completed in S340, CPU 42 outputs the collection command for feeder 25 installed in mounting installation section 26 to loader 18 (S350), and ends this routine. Loader 18 that has received the collection command moves feeder 25 installed in mounting installation section 26 to the standby installation section as necessary.

For example, as illustrated in FIG. 7B, when CPU 21 of mounting device 15 executes mounting job A and ends the production of board S, as illustrated in FIG. 7C, loader 18 exchanges feeder 25, and CPU 21 executes mounting job B. In addition, when CPU 21 ends the production of board S of mounting job B, as illustrated in FIG. 7D, loader 18 exchanges feeder 25, and CPU 21 executes mounting job C. Further, when CPU 21 executes mounting job C and ends the production of board S, loader 18 exchanges feeder 25 as illustrated in FIG. 8A, and CPU 21 executes mounting job D. Furthermore, when mounting job D is executed and the production of board S ends, as illustrated in FIG. 8B, feeder 25 is exchanged, and CPU 21 executes mounting job E. Then, when the last mounting job E of the common setup ends, loader 18 executes a restoration process of restoring the installation state of feeders 25 in the common setup as illustrated in FIG. 8C. When the mounting process by the common setup has ended, CPU 42 notifies worker W of the collective exchange of feeders 25, and worker W who has checked the notification collectively exchanges the feeder group of common setup 2. In mounting device 15, when the empty slot is provided in mounting installation section 26, the position of feeder 25 changes, and thus collective exchange using the feeder magazine changer or the like cannot be performed. In mounting device 15, since the disposition state of feeders 25 in the common setup is restored at the predetermined timing of the mounting process in the common setup, feeders 25 can be collectively exchanged.

Here, a correspondence relationship between the elements of the present embodiment and the elements of the present disclosure will be clarified. Mounting system 10 of the present embodiment corresponds to an example of a mounting system, mounting device 15 corresponds to a mounting device, loader 18 corresponds to a mobile work device, and supervision apparatus 14 corresponds to a supervision apparatus. Supervision control section 41 corresponds to an example of a supervision control section, mounting installation section 26 corresponds to an example of a mounting installation section, buffer installation section 27 and the storage installation section of storage device 13 correspond to an example of a standby installation section, and CPU 51 corresponds to an example of a movement control section.

Supervision apparatus 14 described above is for use in mounting system 10 including mounting device 15 including mounting section 30 that executes the mounting process of component P on board S as the processing target object, component supply section 24 as the supply section that includes mounting installation section 26 in which feeder 25 that holds component P is installed, component supply section 24 being configured to supply component P, and mounting control section 20 that causes mounting section 30 to pick up component P from component supply section 24, and loader 18 as the mobile work device that automatically exchanges feeders 25 between the standby installation section in which the mounting process is not executable and mounting installation section 26. Supervision apparatus 14 includes supervision control section 41 configured to, after feeders 25 in a common setup for installing feeders 25 that hold common component P at a common position in production of multiple types of boards S are installed in mounting installation section 26, at a predetermined timing when the production of board S by the common setup ends, output a restoration command for moving feeder 25 included in the common setup and not located in mounting installation section 26 to an installation position of the common setup to loader 18. In supervision apparatus 14, since the disposition of feeder 25 of the common setup is restored when the production in the common setup ends, feeders 25 can be collectively exchanged, and thus the efficiency can be further improved by shortening an on-line set up time.

Further, loader 18 moves some or all of feeders 25 unnecessary for the current production of board S among feeders 25 included in the multiple types of common setups to the standby installation section. In supervision apparatus 14, since feeder 25 unnecessary for the current production is moved from mounting installation section 26, there is an empty slot in mounting installation section 26, and thus feeder 25 can be easily exchanged, and more efficient mounting process can be executed. Further, supervision control section 41 outputs the restoration command at any one of the predetermined count before or the predetermined time before last mounting job 45 in the common setup ends, when last mounting job 45 in the common setup ends, or after the common setup ends and before mounting job 45 of next production is executed, as the predetermined timing. In supervision apparatus 14, for example, when the predetermined timing is before mounting job 45 ends, the common setup is restored in advance, so that feeders 25 can be collectively exchanged immediately after the production by the common setup ends, and the efficiency can be further improved. In addition, when the end of mounting job 45 is set as the predetermined timing, the production in the common setup can be reliably performed, and the efficiency can be improved by further reducing the waiting time. In addition, when the timing before mounting job 45 of the next production is executed is set as the predetermined timing, it is possible to collectively exchange feeders 25 after the production in the common setup is more reliably executed.

Further, supervision control section 41 monitors the file name being executed for mounting job 45, and outputs the restoration command in accordance with the change in the file name. In supervision apparatus 14, it is possible to improve the efficiency by using the switching of the file name of mounting job 45. Furthermore, in supervision apparatus 14, the standby installation section includes buffer installation section 27 of mounting device 15 from which mounting section 30 cannot pick up component P or a storage installation section provided in storage device 13 that stores feeder 25. In supervision apparatus 14, the feeder can be retracted to buffer installation section 27 or the storage installation section. Furthermore, after outputting the restoration command, supervision apparatus 14 notifies worker W of information indicating that the feeder group included in the common setup is collectively exchanged. In supervision apparatus 14, worker W can collectively exchange the feeder group included in the common setup.

In addition, loader 18 as the mobile work device is for use in mounting system 10 including mounting device 15 including mounting section 30 that executes the mounting process of component P on board S as the processing target object, component supply section 24 as the supply section including mounting installation section 26 in which feeder 25 holding component P is installed, component supply section 24 being configured to supply component P, and mounting control section 20 that causes mounting section 30 to pick up component P from component supply section 24. Loader 18 includes exchange section 54 that automatically exchanges feeders 25 between the standby installation section in which the mounting process is not executable and mounting installation section 26, and movement control section 50 configured to, after feeders 25 in a common setup for installing feeders 25 that hold the common component at a common position in production of multiple types of boards S are installed in mounting installation section 26, at a predetermined timing when the production of board S by the common setup ends, cause exchange section 54 to execute a restoration process of moving feeder 25 included in the common setup and not located in mounting installation section 26 to an installation position of the common setup. In loader 18, since the feeder disposition of the common setup is restored when the production in the common setup ends, feeders 25 can be collectively exchanged, and thus the efficiency can be further improved by shortening an on-line set up time.

In loader 18, movement control section 50 moves some or all of feeders 25 unnecessary for the current production of board S among feeders 25 included in the multiple types of common setups to the standby installation section. In loader 18, since feeder 25 unnecessary for the current production is moved from mounting installation section 26, there is an empty slot in mounting installation section 26, and thus feeder 25 can be easily exchanged, and more efficient mounting process can be executed. In addition, movement control section 50 executes the restoration process at any one of the predetermined count before or the predetermined time before last mounting job 45 in the common setup ends, when last mounting job 45 in the common setup ends, or after the common setup ends and before mounting job 45 of next production is executed, as the predetermined timing. In loader 18, for example, when the predetermined timing is before mounting job 45 ends, the common setup is restored in advance, so that feeders 25 can be collectively exchanged immediately after the production by the common setup ends, and the efficiency can be further improved. In addition, when the end of mounting job 45 is set as the predetermined timing, the production in the common setup can be reliably performed, and the efficiency can be improved by further reducing the waiting time. In addition, when the timing before the mounting job of the next production is executed is set as the predetermined timing, feeders 25 can be collectively exchanged after the production in the common setup is more reliably performed. Furthermore, in loader 18, the standby installation section includes buffer installation section 27 of mounting device 15 from which mounting section 30 cannot pick up component P and/or a storage installation section provided in storage device 13 that stores feeder 25. In loader 18, feeder 25 can be retracted to buffer installation section 27 or the storage installation section.

In addition, mounting system 10 includes mounting device 15 including mounting section 30 that executes the mounting process of component P on board S as the processing target object, component supply section 24 as the supply section including mounting installation section 26 in which feeder 25 holding component P is installed, component supply section 24 being configured to supply component P, and mounting control section 20 that causes mounting section 30 to pick up component P from component supply section 24, supervision apparatus 14 described above, and loader 18 described above. Since mounting system 10 includes supervision apparatus 14 described above and loader 18 described above, it is possible to improve the efficiency by restoring the feeder disposition of the common setup when production in the common setup ends.

It is obvious that the present disclosure is not limited to the above-described embodiment and can be carried out in various modes as long as the modes belong to the scope of the present disclosure.

For example, in the above-described embodiment, the restoration command is output at any one of the predetermined count before or the predetermined time before last mounting job 45 in the common setup ends, when last mounting job 45 in the common setup ends, or after the common setup ends and before mounting job 45 of next production is executed, as the predetermined timing, but the present disclosure is not particularly limited thereto. As the predetermined timing, any one of these four types may be omitted, or a timing other than these four types may be added. In addition, for example, supervision control section 41 may determine whether time to collect feeder 25 disposed in the supply section has arrived each time one mounting job ends, and output the restoration command when it is determined that the time to collect feeder 25 has arrived.

In the above-described embodiment, CPU 42 monitors the file name being executed for the mounting job, and outputs the restoration command in accordance with the change in the file name, but the present disclosure is not particularly limited thereto. CPU 42 may monitor factors other than the change in the file name.

In the above-described embodiment, the standby installation section includes buffer installation section 27 and the storage installation section, but the present disclosure is not particularly limited thereto, and any one of these may be omitted or other installation sections may be included.

In the above-described embodiment, CPU 42 notifies worker W of the information indicating that the feeder group included in the common setup is collectively exchanged after outputting the restoration command, but the present disclosure is not particularly limited thereto, and this processing may be omitted. In addition, in the above-described embodiment, worker W collectively exchanges the feeder group of the common setup, but the present disclosure is not particularly limited thereto, and an automatic conveyance device such as AMR or AGV may be configured to automatically convey between the warehouse and buffer installation section 27, and the feeder group may be collectively exchanged by the automatic conveyance device.

In the above-described embodiment, supervision apparatus 14 outputs the restoration command, but the present disclosure is not particularly limited thereto, and supervisory device 60 may output the restoration command. The function of supervision apparatus 14 may be executed by another control device such as supervisory device 60.

In the above-described embodiment, mounting system 10 includes, in addition to mounting device 15, printing device 11, printing inspection device 12, storage device 13, supervision apparatus 14, mounting inspection device 16, automated guided vehicle 17, loader 18, and reflow device 19, but the configuration is not particularly limited to this, and one or more of the devices described above may be omitted, or a device other than the devices described above may be added.

In the above-described embodiment, the present disclosure is applied to the form of mounting system 10, but the present disclosure may be applied to supervision apparatus 14, loader 18, a supervision method, or a method of controlling loader 18.

Here, the supervision apparatus, the mobile work device, the mounting system, the supervision method, and the method of controlling the mobile work device according to the present disclosure may be configured as follows. For example, the supervision method according to the present disclosure is
a supervision method executed by a computer for use in a mounting system including a mounting device including a mounting section configured to execute a mounting process of a component on a processing target object, a supply section including a mounting installation section in which a feeder that holds the component is installed, the supply section being configured to supply the component, and a mounting control section configured to cause the mounting section to pick up the component from the supply section, and a mobile work device configured to automatically exchange the feeders between a standby installation section in which the mounting process is not executable and the mounting installation section, the supervision method including:
a supervision step of, after the feeders in a common setup for installing the feeders that hold a common component at a common position in production of multiple types of the processing target objects are installed in the mounting installation section, at a predetermined timing when the production of the processing target object by the common setup ends, outputting a restoration command for moving the feeder included in the common setup and not located in the mounting installation section to an installation position of the common setup to the mobile work device.

In this supervision method, similarly to the supervision apparatus described above, since the feeder disposition of the common setup is restored when the production in the common setup ends, the feeders can be collectively exchanged, and thus the efficiency can be further improved by shortening an on-line set up time. In this supervision method, various configurations of the supervision apparatus described above may be adopted, and steps for achieving the respective functions of the supervision apparatus described above may be added.

The method of controlling the mobile work device according to the present disclosure is
a method of controlling a mobile work device by a computer for use in a mounting system including a mounting device including a mounting section configured to execute a mounting process of a component on a processing target object, a supply section including a mounting installation section in which a feeder that holds the component is installed, the supply section being configured to supply the component, and a mounting control section configured to cause the mounting section to pick up the component from the supply section, the mobile work device including an exchange section configured to automatically exchange the feeders between a standby installation section in which the mounting process is not executable and the mounting installation section, the method including:
a movement step of, after the feeders in a common setup for installing the feeders that hold a common component at a common position in production of multiple types of the processing target objects are installed in the mounting installation section, at a predetermined timing when the production of the processing target object by the common setup ends, causing the exchange section to execute a restoration process of moving the feeder included in the common setup and not located in the mounting installation section to an installation position of the common setup.

In the method of controlling the mobile work device, similarly to the mobile work device described above, since the feeder disposition of the common setup is restored when the production in the common setup ends, the feeders can be collectively exchanged, and thus the efficiency can be further improved by shortening an on-line set up time. In the method of controlling the mobile work device, various configurations of the mobile work device described above may be adopted, and steps for achieving the respective functions of the mobile work device described above may be added.

### INDUSTRIAL APPLICABILITY

The present disclosure is applicable to the technical field of a device that picks up and mounts a component.

### REFERENCE SIGNS LIST

10: mounting system, 11: printing device, 12: printing inspection device, 13: feeder storage section, 14: supervision PC, 15: mounting device, 16: mounting inspection device, 17: automated guided vehicle, 18: loader, 19: reflow device, 20: mounting control section, 21: CPU, 22: board processing section, 24: component supply section, 25: feeder, 26: mounting installation section, 27: buffer installation section, 28: slot, 29: connection section, 30: mounting section, 31: head moving section, 32: mounting head, 33: nozzle, 34: imaging section, 35: nozzle station, 36: operation panel, 38: communication section, 39: X-axis rail, 41: supervision control section, 42: CPU, 43: storage section, 44: production plan information, 45: mounting job, 46: selection information, 48: communication section, 49: display section, 50: movement control section, 51: CPU, 52: storage section, 53: accommodation section, 54: exchange section, 55: moving section, 58: communication section, 60: supervision apparatus, 61: overall control section, 62: CPU, 63: storage section, 64: production plan information, 65: mounting job, 68: communication section, 80: execution condition input screen, 81: cursor, 82: selection processing display field, 83: selection input field, 84: summary display field, 86: message display field, 88: return key, 89: confirm key, P: component, S: board, W: worker.

1. A supervision apparatus for use in a mounting system including a mounting device including a mounting section configured to execute a mounting process of a component on a processing target object, a supply section including a mounting installation section in which a feeder that holds the component is installed, the supply section being configured to supply the component, and a mounting control section configured to cause the mounting section to pick up the component from the supply section, and a mobile work device configured to automatically exchange the feeders between a standby installation section in which the mounting process is not executable and the mounting installation section, the supervision apparatus comprising:
a supervision control section configured to, after the feeders in a common setup for installing the feeders that hold a common component at a common position in production of multiple types of the processing target objects are installed in the mounting installation section, at a predetermined timing when the production of the processing target object by the common setup ends, output a restoration command for moving the feeder included in the common setup and not located in the mounting installation section to an installation position of the common setup to the mobile work device.

2. The supervision apparatus according to claim 1, wherein the mobile work device is configured to move some or all of feeders unnecessary for production of a current processing target object among the feeders included in multiple types of common setups to the standby installation section.

3. The supervision apparatus according to claim 1, wherein the supervision control section is configured to output the restoration command at any one of a predetermined count before or a predetermined time before a last mounting job in the common setup ends, when the last mounting job in the common setup ends, or after the common setup ends and before a mounting job of next production is executed, as the predetermined timing.

4. The supervision apparatus according to claim 1, wherein the supervision control section is configured to supervise a file name being executed for the mounting job, and output the restoration command in accordance with a change in the file name.

5. The supervision apparatus according to claim 1, wherein the standby installation section includes a buffer installation section of the mounting device from which the mounting section is not capable of picking up the component and/or a storage installation section included in a storage device configured to store the feeders.

6. The supervision apparatus according to claim 1, wherein the supervision apparatus is configured to notify a worker of information indicating that a feeder group included in the common setup is collectively exchanged after outputting the restoration command.

7. A mobile work device for use in a mounting system including a mounting device including a mounting section configured to execute a mounting process of a component on a processing target object, a supply section including a mounting installation section in which a feeder that holds the component is installed, the supply section being configured to supply the component, and a mounting control section configured to cause the mounting section to pick up the component from the supply section, the mobile work device comprising:
an exchange section configured to automatically exchange the feeders between a standby installation section in which the mounting process is not executable and the mounting installation section; and
a movement control section configured to, after the feeders in a common setup for installing the feeders that hold a common component at a common position in production of multiple types of the processing target objects are installed in the mounting installation section, at a predetermined timing when the production of the processing target object by the common setup ends, cause the exchange section to execute a restoration process of moving the feeder included in the common setup and not located in the mounting installation section to an installation position of the common setup.

8. A mounting system comprising:
a mounting device including a mounting section configured to execute a mounting process of a component on a processing target object, a supply section including a mounting installation section in which a feeder that holds the component is installed, the supply section being configured to supply the component, and a mounting control section configured to cause the mounting section to pick up the component from the supply section,
the supervision apparatus according to claim 1; and
a mobile work device, comprising:
an exchange section configured to automatically exchange the feeders between a standby installation section in which the mounting process is not executable and the mounting installation section; and
a movement control section configured to, after the feeders in a common setup for installing the feeders that hold a common component at a common position in production of multiple types of the processing target objects are installed in the mounting installation section, at a predetermined timing when the production of the processing target object by the common setup ends, cause the exchange section to execute a restoration process of moving the feeder included in the common setup and not located in the mounting installation section to an installation position of the common setup.

9. A supervision method executed by a computer for use in a mounting system including a mounting device including a mounting section configured to execute a mounting process of a component on a processing target object, a supply section including a mounting installation section in which a feeder that holds the component is installed, the supply section being configured to supply the component, and a mounting control section configured to cause the mounting section to pick up the component from the supply section, and a mobile work device configured to automatically exchange the feeders between a standby installation section in which the mounting process is not executable and the mounting installation section, the supervision method comprising:
a supervision step of, after the feeders in a common setup for installing the feeders that hold a common component at a common position in production of multiple types of the processing target objects are installed in the mounting installation section, at a predetermined timing when the production of the processing target object by the common setup ends, outputting a restoration command for moving the feeder included in the common setup and not located in the mounting installation section to an installation position of the common setup to the mobile work device.

10. A method of controlling a mobile work device by a computer for use in a mounting system including a mounting device including a mounting section configured to execute a mounting process of a component on a processing target object, a supply section including a mounting installation section in which a feeder that holds the component is installed, the supply section being configured to supply the component, and a mounting control section configured to cause the mounting section to pick up the component from the supply section, the mobile work device including an exchange section configured to automatically exchange the feeders between a standby installation section in which the mounting process is not executable and the mounting installation section, the method comprising:
a movement step of, after the feeders in a common setup for installing the feeders that hold a common component at a common position in production of multiple types of the processing target objects are installed in the mounting installation section, at a predetermined timing when the production of the processing target object by the common setup ends, causing the exchange section to execute a restoration process of moving the feeder included in the common setup and not located in the mounting installation section to an installation position of the common setup.
